(19) United States
(12) Patent Application Publication
(10) Pub. No.: US 2007/0120203 A1
(43) Pub. Date: May 31, 2007

(54) Semiconductor device and method for manufacturing the semiconductor devices

(75) Inventors: Yoshikazu Yamaoka, Ogaki-shi (JP); Kazunori Fujita, Yoro-Gun (JP); Satoru Shimada, Hashima city (JP); Hideki Mizuhara, Ichinomiya-city (JP); Yasunori Inoue, Ogaki-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/604,359

(22) Filed: Nov. 27, 2006

(30) Foreign Application Priority Data
Nov. 30, 2005 (JP) 2005-347283

(51) Int. Cl. H01L 29/76

(52) U.S. Cl. 257/405

(57) ABSTRACT

A semiconductor device includes a semiconductor substrate on which a source region and a drain region are formed, an insulating film formed on the semiconductor substrate and interposed between the source region and the drain region, a gate electrode formed on the insulating film, metal-bearing particles formed on the interface between the insulation film and the gate electrode, and an insulator which has been changed from a part of metal-bearing particles protruding from an edge of the interface.

### BACKGROUND OF THE INVENTION

1. Field of the Invention

The present invention relates to a semiconductor device and a manufacturing method therefor. More particularly, the present invention relates to a field-effect transistor provided with a gate electrode containing metallic inclusions and a manufacturing method therefor.

2. Description of the Related Art

In recent years, there has been a growing demand for higher speed and lower power consumption of semiconductor integrated circuits. In response, efforts have been made to shorten the gate length, reduce the thickness of the gate insulator, and raise the dielectric constant of the gate insulating film.

The material used for gate electrodes has been polysilicon doped with impurities. However, the use of polysilicon for a gate electrode has involved a problem of increased effective thickness of gate insulating film due to the depletion of the electrode.

As a solution to this problem, Reference (1) in the following Related Art List discloses a structure in which TaN particles are introduced in the polysilicon/oxide silicon interface of MOSFET so as to control the threshold voltage Vth and suppress the depletion effect.

### Related Art List

(1) H. Fujiwara et al., “Flat-band Voltage Tunability and No Depletion Effect of Poly-Si Gate CMOS with Nanometer-size Metal Dots at the Poly-Si/Dielectric Interface”, Extended Abstracts of the 2004 International Conference on Solid State Devices and Materials, Tokyo, 2004, pp. 488-489.

However, there are cases where some of the metallic particles present at the polysilicon/oxide silicon interface protrude from the periphery thereof. And if the device is manufactured without this protrusion removed, then the device can suffer a dielectric breakdown caused by an electric field converging on the protrusion of the metallic particles which are conductive. Also, the metallic particles protruding from the polysilicon/oxide silicon interface may fall off during the manufacturing process, which may adversely affect some subsequent process by metallic pollution.

### SUMMARY OF THE INVENTION

The present invention has been made in view of the foregoing circumstances, and a general purpose thereof is to provide a highly reliable semiconductor device and a manufacturing method therefor.

An advantage of the present invention is its capacity to provide a semiconductor device without leaks due to the metallic content in the gate electrode and a manufacturing method therefor.

In order to solve the above problems, a semiconductor device according to one embodiment of the present invention comprises: a semiconductor substrate on which a source region and a drain region are formed; an insulating film formed on a region of the semiconductor substrate being interposed between the source region and the drain region; a gate electrode formed on the insulating film; a metallic inclusion formed on an interface between the insulation film and the gate electrode; and an insulator which has been changed from a part of the metal inclusion protruding from an edge of the interface.

According to this embodiment, the metallic inclusion protruding from an edge of the interface between the insulating film and the gate electrode is turned into an insulator. As a result, it is unlikely that the electric field will concentrate on the metallic inclusion, compared with a state in which the metallic content, as is, is protruding from the edge. Thereby, the reliability of the semiconductor device can be enhanced.

Another embodiment of the present invention relates also to a semiconductor device. This device comprises: a semiconductor substrate on which a source region and a drain region are formed; an insulating film formed on a region of the semiconductor substrate being interposed between the source region and the drain region; a gate electrode formed on the insulating film; a metallic inclusion formed on an interface between the insulation film and the gate electrode; and an insulator formed in a region where a part of the metal inclusion protruding from an edge of the interface has been detached.

According to this embodiment, the region where the metal inclusion protruding from an edge of the interface between the insulating film and the gate electrode has been fallen off is turned into an insulator. As a result, the electric field concentration on the metallic inclusion is unlikely to occur, compared with a state in which the metallic content, as is, is protruding from the edge and therefore the reliability of the semiconductor device can be enhanced.

A structure may be such that in the interface the width of the gate electrode in a gate length direction is gradually narrowed toward the insulating film.

According to this embodiment, there will be fewer dielectric breakdowns caused by an electric field concentrating on any of salients and edges of the gate electrode, thus further improving the reliability of the semiconductor device.

The metal inclusion or metal-bearing particles preferably contain at least one of W, Si, Ta, Ti, Hf, Al, Pt, Zr, Mo, V, Nb, Cr, Mn, Tc, Re, Fe, Co, Ni, the nitrides thereof and suicides thereof.

As the insulating film, high-dielectric insulating film materials, such as SiON or oxides of Hf, Zr, or Al, may be used singly or in lamination.

Still another embodiment of the present invention relates to a method of manufacturing a semiconductor device. This method comprises: forming an insulating film on a semiconductor substrate; forming a metallic inclusion on the insulating film; forming a gate electrode on the insulating film in such a manner as to cover the metallic inclusion; removing selectively the gate electrode so as to have a desired pattern; and changing a part of the metal inclusion protruding from an edge of an interface between the insulating film and the gate electrode, into an insulating region.

According to this embodiment, the metallic inclusion protruding from an edge of the interface between the insulating film and the gate electrode is transformed to an insulator. As a result, the occurrence of the electric field concentration on the metallic inclusion is suppressed, as compared with a state in which the metallic content, as is, is protruding from the edge. Hence, the reliability of the semiconductor device can be enhanced.

The process of changing the metal-bearing particles into the insulating region is preferably a plasma oxidation in an atmosphere containing the oxygen gas or an annealing in an atmosphere containing the oxygen gas.

Here, the aforementioned metallic inclusion may, for instance, not only be a scattering of spherical metal-bearing particles but also a plurality of metal-bearing particles interconnected with one another in reality. Or they may come in elliptical, cylindrical, polyhedral or other forms. Also, it is not necessary that the arrangement and density of the metallic inclusion formed on the interface are even. Also, the metallic inclusion may take a form of a porous metal-bearing thin film.

It is to be noted that any arbitrary combinations or rearrangement, as appropriate, of the aforementioned constituting elements and so forth are all effective as and encompassed by the embodiments of the present invention and the scope of the invention protected by this patent application.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a schematic cross-sectional view showing a structure of a semiconductor device according to a first embodiment of the present invention;

FIG. 2 is a schematic illustration of an arrangement of metallic contents at the interface of gate electrode and insulation film of a semiconductor device according to a first embodiment as viewed from the gate electrode side;

FIG. 3 is a cross-sectional view schematically showing a manufacturing process for a semiconductor device according to a first embodiment;

FIG. 4 is a cross-sectional view schematically showing a manufacturing process for a semiconductor device according to the first embodiment;

FIG. 5 is a cross-sectional view schematically showing a manufacturing process for a semiconductor device according to the first embodiment;

FIG. 6 is a cross-sectional view schematically showing a manufacturing process for a semiconductor device according to the first embodiment;

FIG. 7 is a cross-sectional view schematically showing a manufacturing process for a semiconductor device according to the first embodiment;

FIG. 8 is a cross-sectional view schematically showing a manufacturing process for a semiconductor device according to the first embodiment;

FIG. 9 is a cross-sectional view schematically showing a manufacturing process for a semiconductor device according to the first embodiment;

FIG. 10 is a cross-sectional view schematically showing a manufacturing process for a semiconductor device according to the first embodiment;

FIG. 11 is a schematic cross-sectional view showing a structure of a semiconductor device according to a second embodiment of the present invention;

FIG. 12 is a schematic illustration of an arrangement of metal contents on the interface between a gate electrode and an insulating film of a semiconductor device according to a second embodiment as viewed from a gate electrode side;

FIG. 13 is a schematic cross-sectional view showing a structure of a semiconductor device according to a third embodiment of the present invention;

FIG. 14 illustrates a realistic arrangement of metallic contents at the interface of gate electrode and insulating film of a semiconductor device according to a first embodiment as viewed from a gate electrode side; and

FIG. 15 illustrates a realistic arrangement of metallic contents at the interface of gate electrode and insulating film of a semiconductor device according to a first embodiment as viewed from a gate electrode side.

### DETAILED DESCRIPTION OF THE INVENTION

The invention will now be described by reference to the preferred embodiments. This does not intend to limit the scope of the present invention, but to exemplify the invention.

### First Embodiment

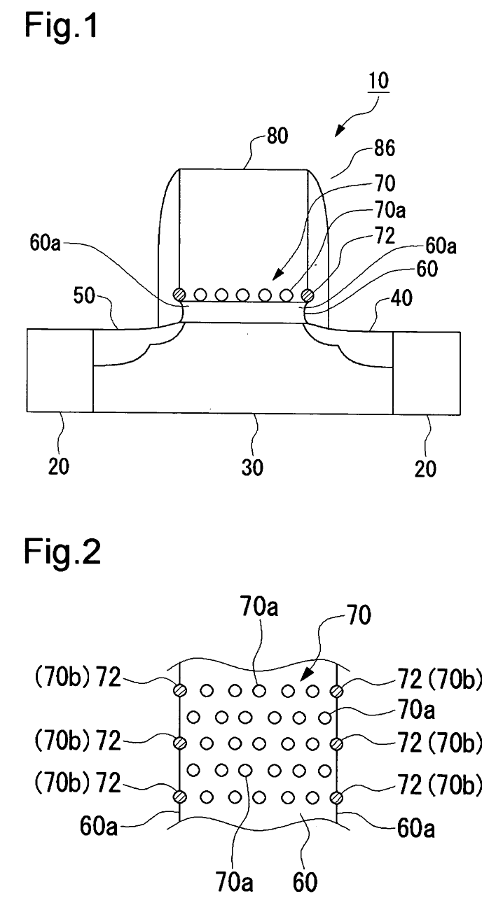

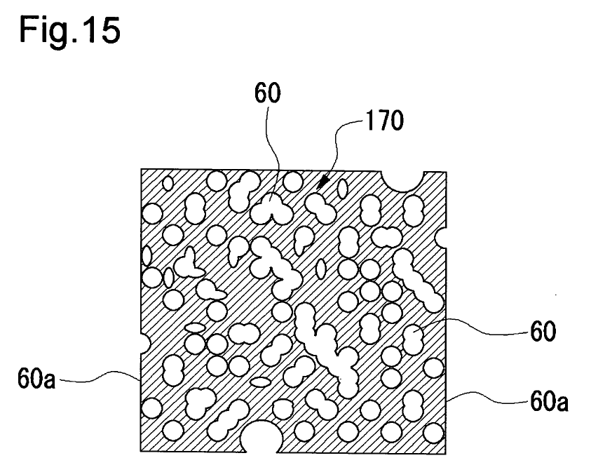

FIG. 1 is a schematic cross-sectional view showing a structure of a semiconductor device 10 according to a first embodiment of the present invention. FIG. 2 is a schematic illustration of an arrangement of metallic inclusions at the interface of gate electrode and insulating film of a semiconductor device 10 according to the first embodiment as viewed from the gate electrode side. FIG. 14 and FIG. 15 are illustrations of a realistic arrangement of metallic inclusions at the interface of gate electrode and insulating film of a semiconductor device 10 according to the first embodiment as viewed from the gate electrode side.

The metallic inclusions therefore may not only be a scattering of spherical metal-bearing particles as shown in FIG. 2 but also a plurality of metal-bearing particles interconnected with one another in reality. Or they may come in elliptical, cylindrical, polyhedral or other forms (see FIG. 14). Also, it is not necessary that the arrangement and density of the metallic inclusions formed on the interface are even. Also, the metallic inclusions may take a form of a porous metal-bearing thin film 170 (see FIG. 15). Hereinbelow, a description will be given of the case of metal-bearing particles as an example of metallic inclusions by referring to FIG. 1 and FIG. 2. For the cases of FIG. 14 and FIG. 15, the same reference numerals are used, but the description thereof will be omitted.

The semiconductor device 10 is comprised of a semiconductor substrate 30 with a source region 40 and a drain region 50 formed thereon, an insulating film 60 formed on the semiconductor substrate 30, a gate electrode 80 formed on the insulating film 60, and metal-bearing particles 70 formed on the interface between the insulating film 60 and the gate electrode 80.

According to the first embodiment, semiconductor substrates 30, which are silicon substrates (hereinafter referred to as Si substrates), are isolated from one another by device-isolating regions 20 using a known method. Also, each semiconductor substrate 30 thus isolated from the other devices is provided with a source region 40 and a drain region 50 with a space in between.

Formed on the semiconductor substrate 30 between the source region 40 and the drain region 50 is the insulating film 60 of oxide silicon (hereinafter referred to as SiO₂). Note that as the insulating film 60, high-dielectric insulating film materials, such as SiON or oxides of Hf, Zr, or Al, may be used singly or in lamination. Such an insulating film can effectively suppress the leak current that may otherwise occur between the semiconductor substrate 30 and the gate electrode 80.

The metal-bearing particles 70 are formed on the insulating film 60, and the gate electrode 80 is formed on top thereof in such a manner as to cover the metal-bearing particles. In other words, the metal-bearing particles 70 are formed on the interface between the insulating film 60 and the gate electrode 80.

In the first embodiment, TiN is used as metal-bearing particles 70, but the metal-bearing particles that can be used are not limited thereto. Such materials as can be turned into an insulator by a chosen process or heat treatment may be used. For example, any of such metals as W, Si, Ta, Ti, Hf, Al, Pt, Zr, Mo, V, Cr, Mn, Tc, Re, Fe, Co, Ni, and Nb and the nitrides or silicides thereof may be appropriately selected and used as the metal-bearing particles.

The metal-bearing particles 70 are formed scattered over the insulating film 60. However, as shown in FIG. 2, the metal-bearing particles 70 include metal-bearing particles 70a, disposed on the interface between the insulating film 60 and the gate electrode 80, in which the whole of the metal-bearing particles is positioned within the gate electrode 80, and metal-bearing particles 70b, which are part of the metal-bearing particles protruding from the periphery 60a of the interface. The protruding metal-bearing particles 70b are turned into insulating particles 72 serving as an insulator, by a process to be described later.

The material used for the gate electrode 80 is polycrystalline silicon (hereinafter referred to as Poly-Si). This arrangement provides an advantage of less complex manufacturing process, compared, for instance, with that for a metallic gate for a CMOS, which requires the use of different metal materials for the NMOS and PMOS structures.

With a semiconductor device 10 as described hereinabove, the depletion effect at the electrode surface can be suppressed even when a material with low charge density, such as Poly-Si, is used for the gate electrode 80, because the metal-bearing particles 70 formed on the interface between the insulating film 60 and the gate electrode 80 can suppress it. The metal-bearing particles protruding from the periphery 60a of the interface between the insulating film 60 and the gate electrode 80 are turned into the insulating particles 72, so that there is a reduction in the metal-bearing particles 70a protruding as a conductive material from the periphery 60a. As a result, the reliability of the semiconductor device improves with the restriction or elimination of dielectric breakdowns that may otherwise be caused by an electric field converging on the protruding metal-bearing particles 70a.

### Method for Manufacturing Semiconductor Devices

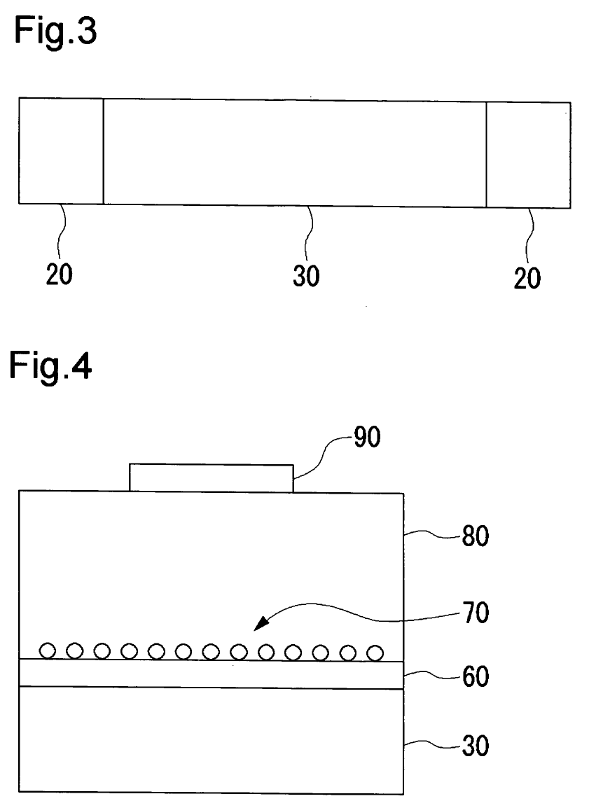

Now the manufacturing method for the above-described semiconductor device will be described by referring to FIGS. 3 through 10. FIGS. 3 through 10 are cross-sectional views schematically showing the manufacturing processes for a semiconductor device according to the first embodiment.

Firstly, as shown in FIG. 3, a semiconductor substrate 30 is isolated from the other devices by device-isolating regions 20, using a known method. According to the first embodiment, the semiconductor substrate 30 is a Si substrate.

Note that the device-isolating regions 20 will be omitted in the description of the subsequent figures.

Next, as shown in FIG. 4, an insulating film 60 of SiO₂ is formed on the semiconductor substrate 30, for instance, by a heat treatment in an oxidizing atmosphere. Following this, metal-bearing particles 70 of TiN are formed on the insulating film by a CVD (Chemical Vapor Deposition) method or a sputtering method.

In the CVD method for forming the metal-bearing particles, the pressure inside a chamber is firstly held at 1.5 Torr, and gases at their respective flow rates of He: 275 sccm, N₂: 300 sccm and He carrier: 225 sccm (TDMAT: 60 mg/min) are supplied thereinto to get 0.5 nm of TiN deposition by two seconds of deposition in a heater atmosphere of 450° C. (substrate temperature: 370° C.) Then, the chamber pressure is held at 1.3 Torr, and gases of H₂: 300 sccm and N₂: 200 sccm are supplied thereinto to effect a plasma processing for six seconds in a heater atmosphere of 450° C. (substrate temperature: 400° C.) and bias conditions of 350 kHz and 700 W. The metal-bearing particles can be formed in this manner. TDMAT (tetrakis dimethyl amino titanium) used here is Ti[N(CH₃)₂]₄.

On the other hand, as a sputtering method for forming the metal-bearing particles, the chamber pressure is held at 4 mTorr, and gases at their respective flow rates of Ar: 35 sccm and N₂: 53 sccm are supplied into the chamber and 0.7 nm of TiN is deposited by sputtering for 2.8 seconds in a heater atmosphere of 150° C. (substrate temperature: 120° C.) and DC 1500 W. The metal-bearing particles can be formed in this manner, too. Note that the typical size of each metal-bearing particle is about 2 nm.

After the formation of the metal-bearing particles 70 on the insulating film 60, a gate electrode 80 of Poly-Si is formed. On the top of the gate electrode 80, a mask 90, which is used to obtain a desired form of the gate electrode by a gate etching to be described later, is placed.

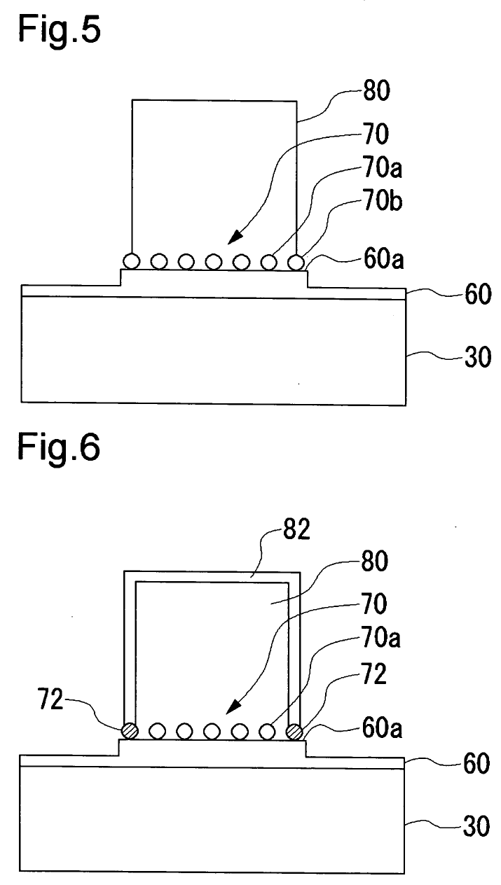

Next, as shown in FIG. 5, an etching process is carried out in which the part of the gate electrode 80 and the metal-bearing particles 70 other than the part covered by the mask is selectively etched by gate etching. The gate etching according to the first embodiment is done by an ECR (Electron Cyclotron Resonance) plasma etching. As for the etching conditions, the chamber pressure is held at 2 mTorr, and gases at their flow rates of HBr/O₂:50/4 sccm are supplied under the conditions of 1800 W microwaves and 20 W bias high-frequency waves.

This etching process exposes the metal-bearing particles 70b protruding from the periphery 60a, which are part of the metal-bearing particles 70 present on the interface between the insulating film 60 and the gate electrode 80. In this state, however, there are possibilities that the electric field converging on the metal-bearing particles 70b at the periphery 60a causes a dielectric breakdown, thus reducing the reliability of the semiconductor device.

Thus, as shown in FIG. 6, a process is carried out in which the metal-bearing particles 70b at the periphery 60a, of the metal-bearing particles 70, are turned into insulators. More specifically, this process is carried out by a plasma oxidation method or an oxygen annealing method.

The preferred conditions for turning the metal-bearing particles into insulators by the plasma oxidation method are holding the chamber pressure at 2 mTorr and supplying O₂ gas to perform the process under the conditions of 1800 W microwaves and 20 W bias high-frequency waves. Also, the preferred conditions for turning the metal-bearing particles into insulators by the oxygen annealing method are supplying O₂ gas at a flow rate of 5 l/min into an atmosphere of normal pressure and 500° C. to perform an annealing for 0.5 hours. In this process, the surface of Poly-Si is also oxidized to form an oxidized film 82.

Through these processes, the metal-bearing particles 70b protruding from the periphery 60a can be turned into the insulating particles 72. More exactly, the TiN particles in this embodiment are turned into an oxide TiO by a process as described above. Since TiO is an insulator, no electric field will concentrate on the TiO even when it is protruding from the periphery 60a.

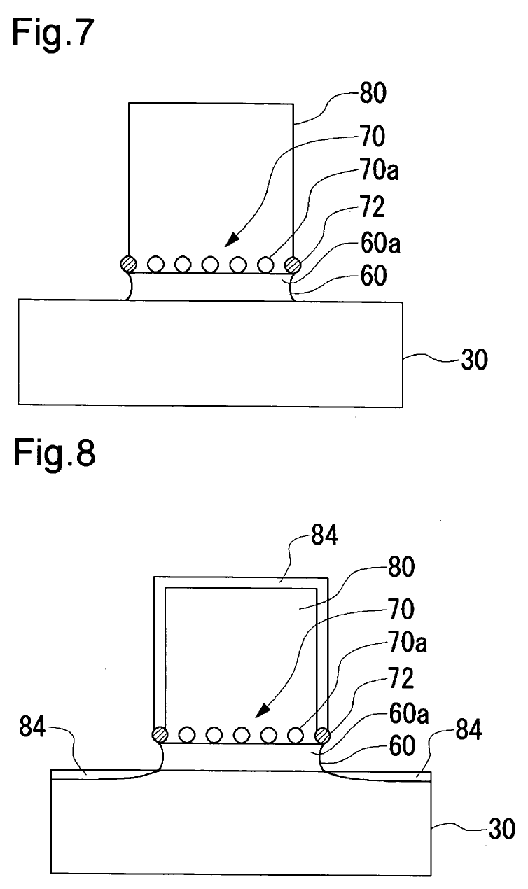

Then, as shown in FIG. 7, the oxidized film 82 formed in the process shown in FIG. 6 is removed by a cleaning process using hydrofluoric acid. In this process, the hydrofluoric acid once removes the part of the insulating film 60 having been damaged in the process shown in FIG. 6 without dissolving the insulating particles 72 of TiO or the like. At this time, the sides of the insulating film 60 are dissolved and thus get dented or recessed slightly toward the center thereof.

Then, as shown in FIG. 8, the reoxidization is carried out to reduce the defects created in the insulating film 60 by the plasma etching or the like in the process shown in FIG. 6. According to the first embodiment, O₂ gas is supplied at a flow rate of 5 l/min into an atmosphere of normal pressure and 850° C. to perform a heat treatment for 1.0 hour. The typical thickness of the oxidized film 84 formed by this operation is about 5 nm.

The process as described above improves the reliability of the semiconductor device by fixing the damage to the insulating film. Also, in this process, the metal-bearing particles 70b protruding from the periphery 60a are turned into the insulating particles 72, so that there will be less effects of the metal-bearing particles 70 on the subsequent thermal oxidizing process. Moreover, even if the insulating particles 72 fall off, there will be less effects of wafer contamination or device contamination on the subsequent processes, compared with the case of the metal-bearing particles 70 falling off.

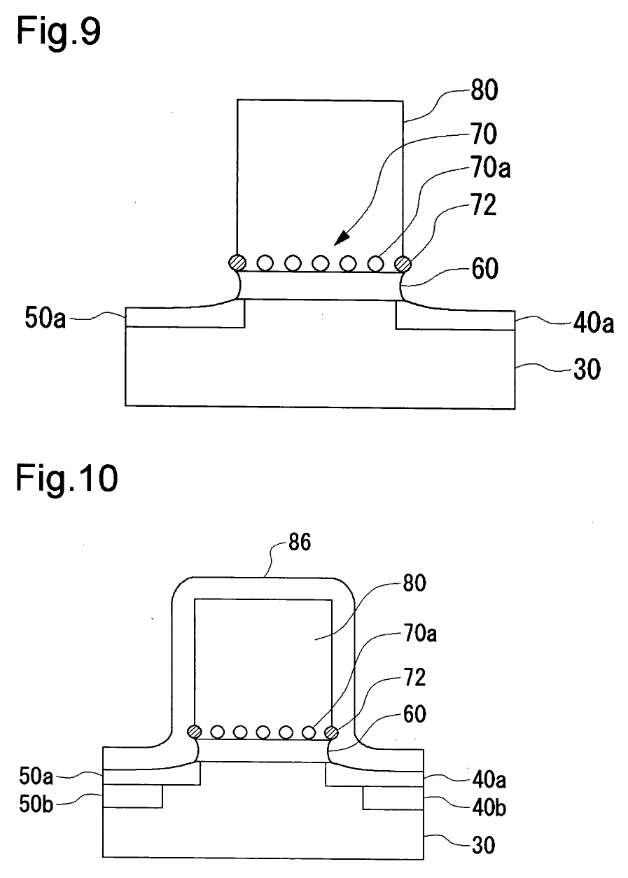

Next, as shown in FIG. 9, the oxidized film 84 formed in the process shown in FIG. 8 is again removed by a cleaning process using hydrofluoric acid.

Then, the source region and the drain region are formed using a desired mask (not shown). For example, the source region and the drain region are formed by ion implantation using such impurities as arsenic (As) or phosphorus (P) as the donor and boron (B) or aluminum (A) as the acceptor.

To be more specific, when an n-channel source/drain is to be formed, an ion implantation of As⁺ is performed with an energy of 2.5 keV to form the source region 40a and the drain region 50a whose dose is 1.0×10¹⁵ cm⁻². Or when a p-channel source/drain is to be formed, an ion implantation of BF₂⁺ is performed with an energy of 3.0 keV to form the source region 40a and the drain region 50a whose dose is 5.0×10¹⁴ cm⁻².

Next, as shown in FIG. 10, when an n-channel source/drain is to be formed, an ion implantation of As⁺ is performed with an energy of 45 keV in the positions deeper than the source region 40a and the drain region 50a, respectively, to form the source region 40b and the drain region 50b whose dose is 5.0×10¹⁵ cm⁻². Or when a p-channel source/drain is to be formed, an ion implantation of B⁺ is performed with an energy of 7.0 keV in the positions deeper than the source region 40a and the drain region 50a, respectively, to form the source region 40b and the drain region 50b whose dose is 5.0×10¹⁵ cm⁻². Then the source regions 40a and 40b and the drain regions 50a and 50b are broadened into the source region 40 and the drain region 50, respectively, by a heat treatment. It is to be noted here that the process of ion implantation to form the source region 40 and the drain region 50 is not limited to the process as described above and that any process viable in the whole manufacturing process may be selected as appropriate.

Following this, a spacer 86 of SiO₂ or the like is deposited to protect the gate electrode 80 and the redundant part of the spacer 86 is removed by etching to complete the manufacture of a semiconductor device 10 as shown in FIG. 1.

According to the manufacturing method for a semiconductor device as described hereinabove, the depletion effect at the electrode surface can be suppressed even when a material with low charge density, such as Poly-Si, is used for the gate electrode 80, because the metal-bearing particles 70 formed on the interface between the insulating film 60 and the gate electrode 80 have the function of suppressing it. Also, the manufacturing method can turn those of the metal-bearing particles protruding from the periphery 60a of the interface between the insulating film 60 and the gate electrode 80 into the insulating particles 72. This results in a reduction of the metal-bearing particles 70a protruding as a conductive material from the periphery 60a, which in turn improves the reliability of the semiconductor device by reducing or eliminating dielectric breakdowns that may otherwise be caused by an electric field concentrating on the protruding metal-bearing particles 70a.

### Second Embodiment

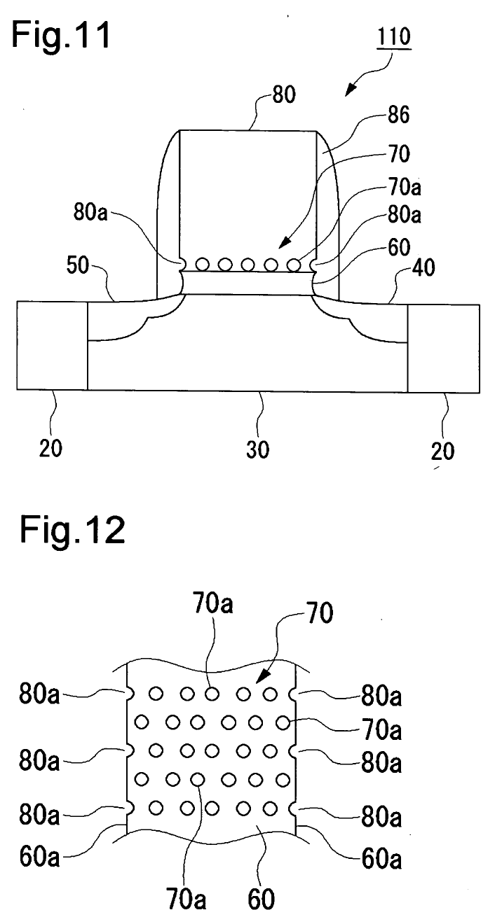

FIG. 11 is a schematic cross-sectional view showing a structure of a semiconductor device 110 according to a second embodiment of the present invention. FIG. 12 is a schematic illustration of an arrangement of metal-bearing particles on the interface between the gate electrode and the insulating film of a semiconductor device 110 according to the second embodiment as viewed from the gate electrode side. In the following explanation, the same reference numerals will be used to indicate the same parts as those of a semiconductor device according to the first embodiment and the description thereof will be omitted as appropriate.

The semiconductor device 110 is comprised of a semiconductor substrate 30 with a source region 40 and a drain region 50 formed thereon, an insulating film 60 formed on the semiconductor substrate 30, a gate electrode 80 formed on the insulating film 60, and metal-bearing particles 70 formed on the interface between the insulating film 60 and the gate electrode 80.

The metal-bearing particles 70 are formed on the insulating film 60, and the gate electrode 80 is formed on top thereof in such a manner as to cover the metal-bearing particles. In other words, the metal-bearing particles 70 are formed on the interface between the insulating film 60 and the gate electrode 80.

Also, the metal-bearing particles 70 are formed scattered over the insulating film 60. However, as shown in FIG. 12, the metal-bearing particles 70 include metal-bearing particles 70a, disposed on the interface between the insulating film 60 and the gate electrode 80, in which the whole of the metal-bearing particles is positioned within the gate electrode 80, and portions 80a in which part of the metal-bearing particles 70b (see FIG. 2) protruding from the periphery 60a of the interface has fallen off. Note that the metallic inclusions may not only be a scattering of spherical metal-bearing particles as shown in FIG. 12 but also a plurality of metal-bearing particles interconnected with one another in reality. Or they may come in elliptical, cylindrical, polyhedral or other forms (see FIG. 14). Also, it is not necessary that the arrangement and density of the metallic inclusions formed on the interface are even.

In the semiconductor device 110 according to the second embodiment, insulators are formed at the portions 80a from which the part of the metal-bearing particles 70b protruding from the periphery 60a, have fallen off during a process similar to the manufacturing method for a semiconductor device according to the first embodiment.

With a semiconductor device 110 as described hereinabove, the depletion effect at the electrode surface can be suppressed even when a material with low charge density, such as Poly-Si, is used for the gate electrode 80, because the metal-bearing particles 70 formed on the interface between the insulating film 60 and the gate electrode 80 have the function of suppressing it. Also, insulators are formed at the portions from which the part of the metal-bearing particles protruding from the periphery 60a of the interface between the insulating film 60 and the gate electrode 80 has fallen off, so that there is a reduction in the metal-bearing particles 70a protruding as a conductive material from the periphery 60a. As a result, the reliability of the semiconductor device improves due to the suppression or elimination of dielectric breakdowns that may otherwise be caused by an electric field converging on the protruding metal-bearing particles 70a.

### Third Embodiment

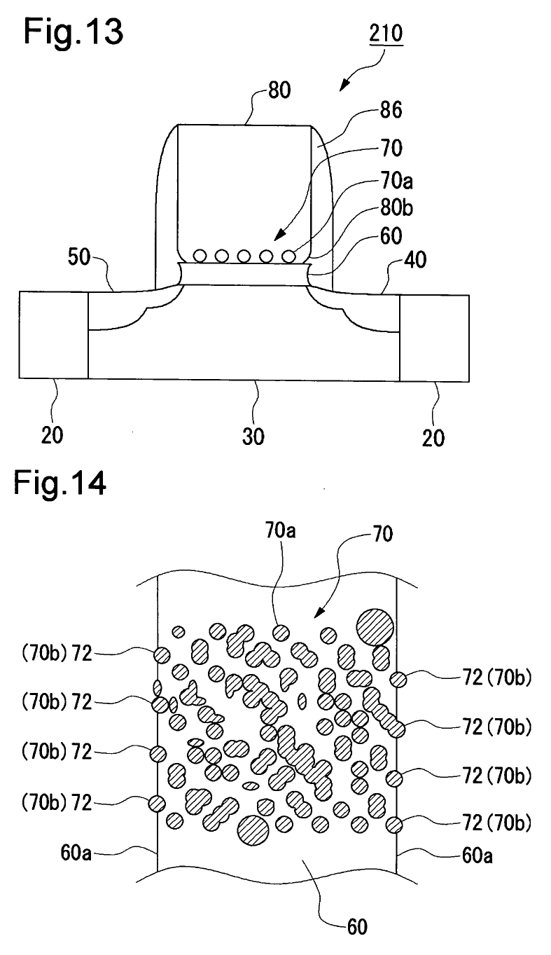

FIG. 13 is a schematic cross-sectional view showing a structure of a semiconductor device 210 according to a third embodiment of the present invention. In the following explanation, the same reference numerals will be used to indicate the same parts as those of a semiconductor device according to the first embodiment and the description thereof will be omitted as appropriate.

The semiconductor device 210 is comprised of a semiconductor substrate 30 with a source region 40 and a drain region 50 formed thereon, an insulating film 60 formed on the semiconductor substrate 30, a gate electrode 80 formed on the insulating film 60, and metal-bearing particles 70 formed on the interface between the insulating film 60 and the gate electrode 80.

The metal-bearing particles 70 are formed on the insulating film 60, and the gate electrode 80 is formed on top thereof in such a manner as to cover the metal-bearing particles. In other words, the metal-bearing particles 70 are formed on the interface between the insulating film 60 and the gate electrode 80.

Also, the metal-bearing particles 70 are formed scattered over the insulating film 60. However, as shown in FIG. 12, the metal-bearing particles 70 include metal-bearing particles 70a, disposed on the interface between the insulating film 60 and the gate electrode 80, in which the whole of the metal-bearing particles is positioned within the gate electrode 80.

The semiconductor device 210 according to the third embodiment has the width in the gate length direction of the periphery 80b of the gate electrode 80 gradually narrowed toward the insulating film 60 at the interface between the insulating film 60 and the gate electrode 80. The structure like this may be realized by selectively etching the gate electrode 80 in preference to the insulating film 60 by an etching process (FIG. 5) in the first embodiment or by any known method.

With a semiconductor device 210 as described hereinabove, the depletion effect at the electrode surface can be suppressed even when a material with low charge density, such as Poly-Si, is used for the gate electrode 80, because the metal-bearing particles 70 formed on the interface between the insulating film 60 and the gate electrode 80 have the function of suppressing it. Also, the width in the gate length direction of the periphery 80b of the gate electrode 80 is gradually narrowed toward the insulating film 60, so that there will be fewer dielectric breakdowns caused by an electric field concentrating on any of salients and edges of the electrode, thus further improving the reliability of the semiconductor device.

The present invention is not limited to the above-described embodiments only, and it is understood by those skilled in the art that various modifications such as changes in design may be made based on their knowledge and that the embodiments added with such modifications are also within the scope of the present invention.

The above-described semiconductor devices can be suitably used for circuits such as CMOS and dual-gate transistors.

While the preferred embodiments of the present invention have been described using specific terms, such description is for illustrative purposes only, and it is to be understood that changes and variations may be made without departing from the spirit or scope of the appended claims.

What is claimed is:

1. A semiconductor device, comprising:
a semiconductor substrate on which a source region and a drain region are formed;
an insulating film formed on a region of said semiconductor substrate being interposed between the source region and the drain region;
a gate electrode formed on said insulating film;
a metallic inclusion formed on an interface between said insulation film and said gate electrode; and
an insulator which has been changed from a part of said metal inclusion protruding from an edge of the interface.

2. A semiconductor device, comprising:
a semiconductor substrate on which a source region and a drain region are formed;
an insulating film formed on a region of said semiconductor substrate being interposed between the source region and the drain region;
a gate electrode formed on said insulating film;
a metallic inclusion formed on an interface between said insulation film and said gate electrode; and
an insulator formed in a region where a part of said metal inclusion protruding from an edge of the interface has been detached.

3. A semiconductor device according to claim 1, wherein a structure is such that in the interface the width of said gate electrode in a gate length direction is gradually narrowed toward said insulating film.

4. A semiconductor device according to claim 2, wherein a structure is such that in the interface the width of said gate electrode in a gate length direction is gradually narrowed toward said insulating film.

5. A method of manufacturing a semiconductor device, the method comprising:
forming an insulating film on a semiconductor substrate;
forming a metallic inclusion on the insulating film;
forming a gate electrode on the insulating film in such a manner as to cover the metallic inclusion;
removing selectively the gate electrode so as to have a desired pattern; and
changing a part of the metal inclusion protruding from an edge of an interface between the insulating film and the gate electrode, into an insulating region.
